(19) United States
(12) Patent Application Publication
(10) Pub. No.: US 2023/0394201 A1
(43) Pub. Date: Dec. 7, 2023

(54) SIMULATION POST PROCESSOR FOR A DUAL-MODE POWER AMPLIFIER

(71) Applicant: Skyworks Solutions, Inc., Irvine, CA (US)

(72) Inventor: Neal J. Tuffy, Great Shelford (GB)

(21) Appl. No.: 18/195,265

(22) Filed: May 9, 2023

Related U.S. Application Data
(60) Provisional application No. 63/340,835, filed on May 11, 2022.
(60) Provisional application No. 63/340,838, filed on May 11, 2022.
(60) Provisional application No. 63/340,882, filed on May 11, 2022.

(51) Int. Cl. G06F 30/27; H03F 3/21

(52) U.S. Cl. CPC G06F 30/27; H03F 3/21

(57) ABSTRACT

A dual-mode power amplifier simulation system is provided. The dual-mode power amplifier system includes a trained machine learning model that is trained with first simulation results associated with a first power amplifier circuit and measured results associated with a physical implementation of the first power amplifier circuit. The trained machine learning model is configured to generate augmented simulation results. In addition, a simulator executes on one or more computer processors that simulates a dual-mode power amplifier circuit and generates dual-mode simulation results. A post processor including the trained machine learning model executes on one or more computing devices with computer-executable instructions that, when executed, causes the post processor to augment the dual-mode simulation results for the dual-mode power amplifier based on the trained machine learning model associated with the first power amplifier circuit.

### INCORPORATION BY REFERENCE TO ANY PRIORITY APPLICATIONS

Any and all applications, if any, for which a foreign or domestic priority claim is identified in the Application Data Sheet of the present application are hereby incorporated by reference under 37 CFR 1.57.

### TECHNICAL FIELD

Embodiments of this disclosure relate to machine learning models that augments electronic circuit simulations.

### COPYRIGHT NOTICE

A portion of the disclosure of this patent document contains material which is subject to copyright protection. The copyright owner has no objection to the facsimile reproduction by anyone of the patent document and/or the patent disclosure as it appears in the United States Patent and Trademark Office patent file and/or records, but otherwise reserves all copyrights whatsoever.

### BACKGROUND

Modern electronic circuits can include, but are not limited to integrated circuits, semiconductor circuits, radio-frequency circuits, and mixed-signal integrated circuits. As improvements in technology advance, the complexity of modern electronic circuits continues to increase. Also, the growing complexity, and the high cost of fabricating prototypes has led to the development of computer programs that simulate the operation of electronic circuits. These electronic circuit simulators aid a designer in verifying the operation of the circuit before resources are committed to the fabrication of prototypes. Furthermore, simulating an electronic circuit's behavior before building it greatly improves efficiency and provides insights into the operational behavior and the stability of the circuit design.

Conventional integrated circuit simulators utilize mathematical models to replicate the behavior of a physical circuit. The trend towards increasing operational frequencies, energy efficiency, and reliability, however, requires components to operate under conditions that are becoming more nonlinear. Also, the wider bandwidths of modern signal formats, such as, but not limited to, one or more of 2G, 3G, 4G (including LTE, LTE-Advanced, and/or LTE-Advanced Pro), 5G, wireless local area network (WLAN) (for instance, Wi-Fi), wireless personal area networks (WPAN) (for instance, LTE-M, Bluetooth and/or ZigBee), wireless metropolitan network (WMAN) (for instance, WiMAX) can introduce complex modulation formats, including more complicated signals with higher peak-to-average ratios especially when two or more are combined together in mixed-mode signal devices.

Still further, components such as transistors fabricated in semiconductor materials, such as gallium nitride (GaN), and other semiconductor materials, such as gallium arsenide (GaAs), may exhibit complicated nonlinear dynamical effects in response to complex modulation signals. Consequently, powerful and sophisticated nonlinear simulation models are needed to accurately and robustly incorporate these various effects that impact performance characteristics of the nonlinear integrated circuits.

For example, a large-signal model is a model that is acceptably accurate over a large range of input signals. For transistors and diodes, this model is polynomial or exponential, which increases mathematical complexity. A small signal model, on the other hand, restricts signals to small variations so that over the range of these smaller variations the response can be approximated as being linear, which is less complex to mathematically represent. Moreover, conventional simulators will often use component-specific models for different components in a circuit's topology.

Additionally, significant sources of error exist in the simulation of dynamic error vector magnitude (EVM) performance, including, dynamic AM/AM (Amplitude to Amplitude Modulation) and AM/PM (Amplitude to Phase Modulation) distortion modeling errors, error in capturing memory and thermal effects, and errors in EM modeling and the interconnection of multiple EM blocks in a simulation. Random errors such as component tolerances and process variation can also form a significant source of measurement to simulation error.

Furthermore, simulation models are typically created based on a variety of disparate and often limited measurements. Consequently, the models do not sufficiently separate all dynamic effects from one another. As a result, simulation models can differ significantly from physical operating conditions which can lead to design errors, operational inconsistencies, production delays and design inefficiencies.

To compensate for these inconsistencies, designers often seek to improve a circuit simulator by comparing the simulation results with actual operating results and making adjustments to the simulator. The errors in simulation results are then overcome by time consuming lab-based tuning with many variants. This is often referred to as “backfitting” the simulation models and can include, for example, adding parasitic circuit offsets. Although this may lead to simulation results that more closely match a small set of real-world results, adding the parasitic circuit offsets is often by trial and error, with a manual, subjective approach that requires design time and added simulation time. Furthermore, even when a designer has improved simulator accuracy with backfitting, the adaptions typically lead to an “overfit” model of the circuit, which ultimately yields poor prediction of future results over a wide range of operating conditions.

Thus, conventional simulation tools continue to suffer from inconsistency issues that result in lost productivity. Also, the lab time required to overcome simulation errors continues to increase, particularly in the case of multi-mode power amplifier circuity. This, in turn, adversely increases development time and cost.

### SUMMARY

For purposes of summarizing the invention, certain aspects, advantages and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

In various embodiments, an electronic circuit simulation post-processing system comprises: a trained machine learning model that is trained with first simulation results associated with a first electronic circuit and measured results obtained from a physical implementation of the first electronic circuit, the trained machine learning model configured to generate augmented simulation results; a simulator executing on one or more computer processors that simulate a second electronic circuit that is different than the first electronic circuit and generates second simulation results; and a post processor including the trained machine learning model that executes on one or more computing devices with computer-executable instructions that, when executed, causes the post processor to augment the second simulation results based on the trained machine learning model.

In one or more embodiments, the trained machine learning model is further trained with bill of material information about the first electronic circuit. In another embodiment, the trained machine learning model further receives bill of material information about the second electronic circuit. In yet another embodiment, the first and second electronic circuits are analog circuits. In a further embodiment, the computer-executable instructions, when executed, further causes the one or more computing devices to: retrain the trained machine learning model using second measured results obtained from the second electronic circuit; and transmit the retrained machine learning model to the post processor such that the post processor uses the retrained machine learning model generate augmented simulation results associated with a third electronic circuit.

In certain embodiments, the trained machine learning model uses a gradient tree boosting, ensemble model. In another embodiment, the trained machine learning model uses at least one of the group consisting of: linear regression, least absolute shrinkage and selection operator (LASSO), support vector regression (SVR), random forest algorithms, or bayesian ridge regression. In an additional embodiment, the trained machine learning model is trained to augment simulation results associated with at least one of the group consisting of: output power, error vector magnitude, current, and an output matching network (OMN).

In one or more embodiments, the first simulation results, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In certain embodiments, the trained machine learning model reduces errors in the second simulation results, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In another embodiment, computer-executable code generates first simulation results corresponding to the measured results.

In various embodiments, a computer-implemented method comprises: storing a trained machine learning model that is trained with first simulation results associated with a first electronic circuit and measured results obtained from a physical implementation of the first electronic circuit; generating, with one or more computer processors, second simulation results associated with a second electronic circuit that is different than the first electronic circuit; and augmenting the second simulation results with the trained machine learning model that executes on one or more computing devices with computer-executable instructions.

In other embodiments, the trained machine learning model is further trained with bill of material information about the first electronic circuit. In another embodiment, the trained machine learning model further receives bill of material information about the second electronic circuit. In a further embodiment, the first and second electronic circuits are analog circuits.

In certain embodiments, a method comprises: retraining the trained machine learning model using second measured results obtained from the second electronic circuit; and augmenting third simulation results associated with a third electronic circuit with the retrained machine learning model.

In other embodiments, the trained machine learning model uses a gradient tree boosting, ensemble model. In another embodiment, the trained machine learning model uses at least one of the group consisting of: linear regression, least absolute shrinkage and selection operator (LASSO), support vector regression (SVR), random forest algorithms, or bayesian ridge regression. In a further embodiment, the trained machine learning model is trained to augment simulation results associated with at least one of the group consisting of: output power, error vector magnitude, current, and an output matching network (OMN).

In certain embodiments, the first simulation results, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In one or more embodiments, the trained machine learning model reduces errors in the second simulation results, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In a further embodiment, computer-executable code generates first simulation results corresponding to the measured results.

In various embodiments, electronic circuit simulation system comprises: simulation results associated with a simulation of a first electronic circuit; measured results associated with a physical implementation of the first electronic circuit; and the one or more computer processors having computer-executable instructions that, when executed, cause the one or more computer processors to train a machine learning model using the simulation results and the measured results to create a trained machine learning model that is used to augment simulation results generated by the simulator for a second electronic circuit.

In other embodiments, the trained machine learning model of the electronic circuit simulation system is further trained with bill of material information about the first electronic circuit. In another embodiment, the trained machine learning model further receives bill of material information about the second electronic circuit. In yet another embodiment, the first and second electronic circuits are analog circuits. In further embodiments, computer-executable instructions, when executed, further causes the one or more computer processors to retrain the trained machine learning model using second measured results obtained from the second electronic circuit.

In one or more embodiments, the trained machine learning model of the electronic circuit simulation system uses a gradient tree boosting, ensemble model. In other embodiments, the trained machine learning model uses at least one of the group consisting of: linear regression, least absolute shrinkage and selection operator (LASSO), support vector regression (SVR), random forest algorithms, or bayesian ridge regression. In further embodiments, the trained machine learning model is trained to augment simulation results associated with at least one of the group consisting of: output power, error vector magnitude, current, and an output matching network (OMN).

In certain embodiments, the simulation results associated with the first electronic circuit, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In other embodiments, the trained machine learning model of the electronic circuit simulation system reduces errors in the simulation results associated with the second electronic circuit, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In further embodiments, computer-executable code generates first simulation results corresponding to the measured results.

In various embodiments, a computer-implemented method comprises: accessing simulation results associated with a simulation of a first electronic circuit; accessing measured results associated with a physical implementation of the first electronic circuit; and training a machine learning model using the simulation results and the measured results to create a trained machine learning model to create a trained machine learning model that is used as a post processor to augment simulation results associated with a second electronic circuit.

In other embodiments, the trained machine learning model is further trained with bill of material information about the first electronic circuit. In additional embodiments, the trained machine learning model further receives bill of material information about the second electronic circuit. In further embodiments, the first and second electronic circuits are analog circuits.

In one or more embodiments, a computer-implemented method further comprises: retraining the trained machine learning model using second measured results obtained from the second electronic circuit; and augmenting third simulation results associated with a third electronic circuit with the retrained machine learning model.

In certain embodiments, the trained machine learning model uses a gradient tree boosting, ensemble model. In other embodiments, the trained machine learning model uses at least one of the group consisting of: linear regression, least absolute shrinkage and selection operator (LASSO), support vector regression (SVR), random forest algorithms, or bayesian ridge regression. In further embodiments, the trained machine learning model is trained to augment simulation results associated with at least one of the group consisting of: output power, error vector magnitude, current, and an output matching network (OMN).

In other embodiments, the simulation results associated with the first electronic circuit, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In further embodiments, the trained machine learning model reduces errors in the second simulation results associated with the second electronic circuit, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In additional embodiments, computer-executable code generates first simulation results corresponding to the measured results.

In various embodiments, a dual-mode power amplifier simulation system comprises: a trained machine learning model that is trained with first simulation results associated with a first power amplifier circuit and measured results associated with a physical implementation of the first power amplifier circuit, the trained machine learning model is configured to generate augmented simulation results; a simulator executing on one or more computer processors that simulates a dual-mode power amplifier circuit and generates dual-mode simulation results; and a post processor including the trained machine learning model that executes on one or more computing devices with computer-executable instructions that, when executed, causes the post processor to augment the dual-mode simulation results for the dual-mode power amplifier based on the trained machine learning model associated with the first power amplifier circuit.

In other embodiments, the trained machine learning model is further trained with bill of material information about the first power amplifier circuit. In yet other embodiments, the trained machine learning model further receives bill of material information about the dual-mode power amplifier circuit. In further embodiments, the first power amplifier circuit and the dual mode power amplifier circuit are multi-chip modules.

In certain embodiments, the computer-executable instructions, when executed, further causes the one or more computer processors to retrain the trained machine learning model using second measured results obtained from the second electronic circuit. In additional embodiments, the trained machine learning model uses a gradient tree boosting, ensemble model. In further embodiments, the trained machine learning model uses at least one of the group consisting of: linear regression, least absolute shrinkage and selection operator (LASSO), support vector regression (SVR), random forest algorithms, or bayesian ridge regression.

In various embodiments, the trained machine learning model of the dual-mode power amplifier simulation system is trained to augment simulation results associated with at least one of the group consisting of: output power, error vector magnitude, current, and an output matching network (OMN). In further embodiments, the simulation results associated with the first power amplifier circuit, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In certain embodiments, the trained machine learning model of the dual-mode power amplifier simulation system reduces errors in the simulation results associated with the dual-mode power amplifier circuit, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In one or more additional embodiments, computer-executable code that generates first simulation results corresponding to the measured results.

In various embodiments, a computer-implemented method comprises: storing a trained machine learning model that is trained with first simulation results associated with a first power amplifier circuit and measured results obtained from a physical implementation of the first power amplifier circuit; generating, with one or more computer processors, second simulation results associated with a dual-mode power amplifier circuit that is different than the first power amplifier circuit; and augmenting the second simulation results with the trained machine learning model that executes on one or more computing devices with computer-executable instructions.

In other embodiments, the trained machine learning model is further trained with bill of material information about the first power amplifier electronic circuit. In additional embodiments, the trained machine learning model further receives bill of material information about the dual mode power circuit. In further embodiments, the first power amplifier circuit includes a mode switch to adjust an output matching impedance, and the dual-mode power amplifier has an array of mode select switches to adjust an output matching impedance.

In one or more embodiments, the computer-implemented method further comprises: retraining the trained machine learning model using second measured results obtained from the dual-mode power amplifier circuit; and augmenting third simulation results associated with another dual-mode power amplifier circuit with the retrained machine learning model.

In other embodiments, the trained machine learning model uses a gradient tree boosting, ensemble model. In additional embodiments, the trained machine learning model uses at least one of the group consisting of: linear regression, least absolute shrinkage and selection operator (LASSO), support vector regression (SVR), random forest algorithms, or bayesian ridge regression. In further embodiments, the trained machine learning model is trained to augment simulation results associated with at least one of the group consisting of: output power, error vector magnitude, current, and an output matching network (OMN).

In certain embodiments, the first simulation results, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

In other embodiments, the trained machine learning model reduces errors in the second simulation results, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors. In additional embodiments, the computer-implemented method further comprises computer-executable code that generates first simulation results corresponding to the measured results.

### BRIEF DESCRIPTION OF THE DRAWINGS

FIG. 1 illustrates a block diagram illustrating the operations performed to train a machine learning model for augmenting simulation results in an embodiment.

FIG. 2 illustrates a block diagram illustrating the operations performed to train a machine learning model for augmenting simulation results in an embodiment.

FIG. 3 illustrates a block diagram illustrating an exemplary post-processing simulation system to augment simulation results associated with a second simulation.

FIG. 4 illustrates an exemplary iterative design process.

FIG. 5 depicts some salient operations of a method for training a machine language model according to an illustrative embodiment of the invention.

FIG. 6 depicts some salient operations of a method for augmenting simulation results associated with a second simulation.

FIG. 7A is a schematic diagram of an example multi-mode power amplifier system according to an embodiment. FIG. 7B is a table of signal values for the multi-mode power amplifier system of FIG. 7A for two modes according to an embodiment. FIG. 7C is a table of signal values for the multi-mode power amplifier system of FIG. 7A for six modes according to an embodiment.

FIG. 8 is schematic diagram of example multi-mode power amplifier system according to an embodiment.

FIG. 9 provides an exemplary scatter plot that compares unaugmented simulation results with augmented simulation results.

### DETAILED DESCRIPTION

Certain embodiments of the disclosed technology improve the accuracy of simulation models for electronic circuitry. A designer creates a circuit design and inputs the circuit design into a simulation model. The simulation model then outputs simulation results that predict how the circuit design will operate. In addition, measured results are obtained from a physical implementation of the electronic circuit. The simulated results and the measured results from the physical implementation are used to train a machine learning model to correct for errors or inconsistencies in the simulation results. The machine learning model is then used to augment or correct future simulation results.

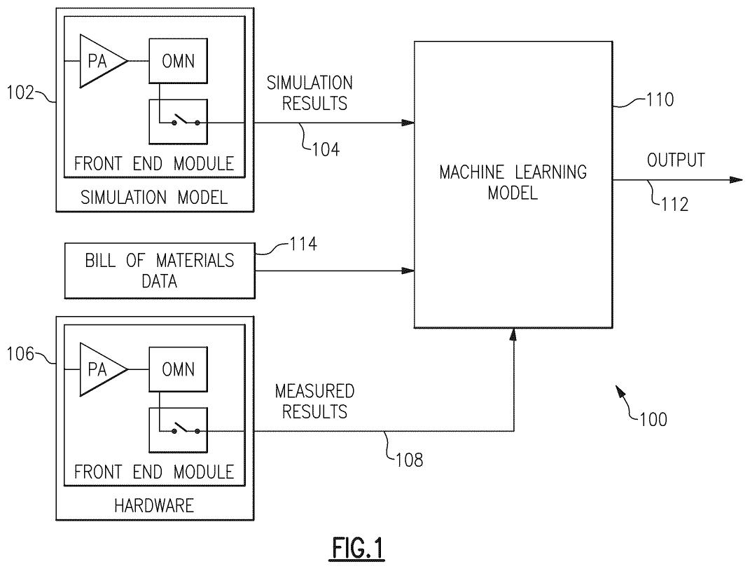

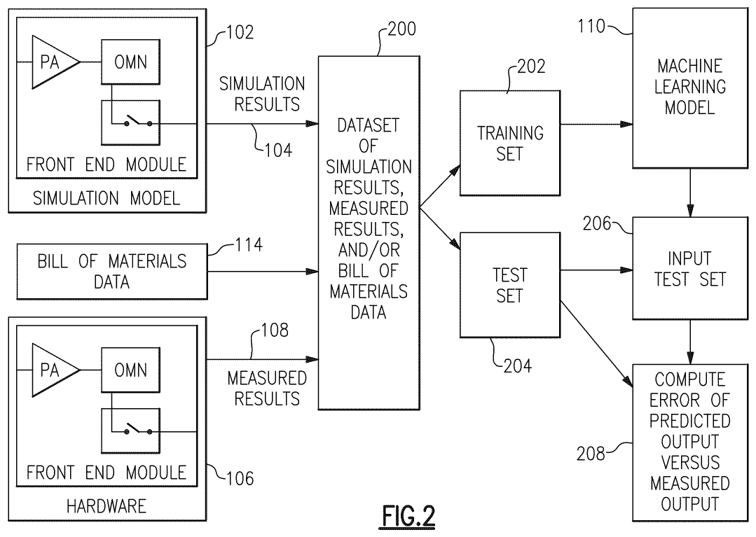

FIG. 1 is a flow diagram illustrating a machine learning system 100. The machine learning system 100 trains a machine learning model 110 to augment simulation results in accordance with certain embodiments of the disclosed technology.

Circuit designers typically rely on electronic design automation (EDA) tools from, for instance, Mentor Graphics®, Cadence Design Systems Inc., or Agilent Technologies Advanced Design System (ADS), Verilog-AMS, which is an analog and mixed signal derivative of the Verilog hardware description language Verilog-HDL. The EDA tools typically describe a circuit design in terms of a list of nodes and the components connected to each node, often referred to as a net list. A net list typically is a text-based representation of a circuit or of a subset of components of a circuit. The definition of the circuit design is often referred to as the bill of materials (BOM) of the circuit.

### Circuit Simulation

To simulate the circuit design, the net list or other circuit definition is provided to a simulation model 102. Each component in the circuit design may be viewed by the simulation model 102 as a device that sources or sinks a current whose value is determined by the voltage at the node to which it is connected, and possibly, by the previous or subsequent voltages associated with the node in question. The user may define particular components or utilize a library of standard components provided with the simulation model. Simulation models may include models provide by SPICE, Advanced Design System (ADS) from Keysight Technologies, MATLAB®, Simulink® from The MathWorks, the PLL Noise Analyzer™ from Berkeley Design Automation Inc, to mention a few.

As illustrated in FIG. 1, information pertaining to one or more parameters of a circuit design are received and simulated by the simulation model 102. The circuit design net list may include a variety of components such as resistors, transistors, capacitors, inductors, diodes, operational amplifiers, voltage sources, current sources, power amplifiers, transmission lines and the like. The parameters for the individual components may include, for example, resistance, current, impedance, inductance, parasitic capacitance, transmission line length, transmission line width, material dielectric constant, semiconductor materials, and geometry. As described below, embodiments of the invention are applicable to many types of simulation models, and the circuit simulation model described with reference to the figures are exemplary.

Certain embodiments are directed to different design circuits, including, but not limited to, circuits that include radio-frequency components, surface mount components, Bluetooth transceivers, WiFi transceivers, wireless local area network (WLAN) transceivers, dual mode Bluetooth and wireless local area network (WLAN) transceivers, front end modules, power amplifiers, mixed-mode circuitry and other radio frequency circuits .

Various simulation parameters are used by the simulation model when running a simulation. The simulation parameters, or simulation inputs, can include by way of example, load and the type and amount of surface mount components, power amplifier variables such as inductor data, capacitance data, input matching network (IMN) data, IMN inductor data, IMN capacitor data, output matching network (OMN) data, OMN inductor data, OMN capacitor data, resistance data, resistance data, transistor base resistance (RBB), current, voltage, frequency, wifi enable, multichip data, circuit architectural information, reference currents, voltage values, frequency, type of power amplifier, multi-chip module (MCM) data, silicon implementation data, and the like.

The simulation model 102 generates simulation results 104 based on the definition of the circuit design and the simulation parameters. In one embodiment, the simulation model 102 in FIG. 1 illustrates a front end circuit or module (FEM) used in radio frequency communications. In other embodiments, the simulation model 102 can simulate any type of analog circuit design. In yet other embodiments, the simulation model 102 can simulate analog circuitry of digital circuitry or the combination of both.

The simulation results 104 may include any simulated event or other statistics generated by the simulation model 102. By way of example, the simulation results 104 may include a dataset of generated values that may include power levels, real and imaginary values, OMN loss, EVM performance, current, and power gain to name a few. Typically when simulating a circuit design, the inputs are varied to obtain a range of simulation results 104.

The simulation results 104 may include waveforms, and need not be static values. That is, a simulation result 104 in some embodiments may be a collection of values as they change over time. Further, many different simulation results 104 may be produced for the instances of the simulation corresponding to different simulation inputs. Furthermore, the simulation results 104 may reflect multiple simulations with varying parameters. Still further, in some embodiments the simulation results 104 may be determined in the frequency domain, while other simulation results may be determined in the in the time domain. The simulation results 104 may further include large signal simulation data, small signal simulation data, or a combination thereof.

The simulation results 104 are stored in a dataset that correlates the simulation results 104 with the simulation values used to generate the simulation results 104. Thus, the dataset indicates the simulation results 104 that were generated by the simulation model 102 for different simulation values.

### Testing Hardware

The circuit design hardware 106 is constructed, tested, and measured. During testing, inputs are applied to the hardware 106, and the outputs of the hardware 106 are measured to generate the measured results 108. The measured results 108 represent the performance of the hardware 106 in response to various inputs.

The circuit design hardware 106 may correspond, for example, to a circuit design used for simulation as described above. In measuring the circuit design hardware 106, the user may use test probes, oscilloscopes, Vector Network Analyzers (VNAs), and other test measurement equipment to make actual physical connections to one or more test points on the circuit design hardware 106 such as inputs, output pins, or individual components to acquire output data, waveforms, or other measurements. This measured data is illustrated as the measured results 108 in FIG. 1.

The measured results 108 may include any measurable output of the hardware 106, including, but not limited to power levels, voltage levels, EVM performance, current, and power gain to name a few. For example, the measured results 108 may the termination load or output load often referred to as the Zload. In some embodiments, the Zload can include an antenna impedance. The measured results 108 may also include the measurement test temperature.

Another measured result 108 can include a variety of test types such as large signal test, small signal test, or scattering parameters test. Scattering parameters, or S-parameters are defined in terms of incident and reflected traveling waves and typically describe the input-output relationship between two ports or terminals. The S-parameters may include S11 which is a reflection coefficient for port 1, S22 which is a reflection coefficients for port 2, S12 which is a transmission coefficient from port 2 to port 1, and S21 is a transmission coefficient from port 1 to port 2. S-parameters are usually specified in decibels (dB).

Another measured result 108 can include modulation type such as modulation types defined by the Modulation Coding Scheme (MCS) index and the Enhanced Data Rate (EDR). The Modulation Coding Scheme (MCS) index is an existing industry metric based on several parameters of a Wi-Fi connection between a client device and a wireless access point, including data rate, channel width, and the number of antennas or spatial streams in the device. The Enhanced Data Rate (EDR) is an industry standard modulation scheme associated with the Bluetooth standard.

Another measured result 108 can include the duty cycle of a waveform. Yet another measured result 108 can include a waveform burst length (Burst_Len). Still another measure result 108 can include the location and testbench used for hardware measurements (Test_site).

The measured results 108 may also include waveforms, and need not be static values. That is, a measured result 108 in some embodiments may be a collection of values as they change over time. Further, many different measured results 108 may be produced. Furthermore, the measured results 108 may reflect multiple simulations with varying parameters. Still further, in some embodiments the measured results 108 may be determined in the frequency domain, while other simulation results may be determined in the in the time domain. In some instances, the measured results 108 may include a single output result in response to the variance of different inputs. In other instances, the measured results may include multiple output results associated with variances in multiple inputs.

The measured results 108 are stored in a dataset that correlates the measured results 108 with the hardware inputs used to generate the measured results 108. Thus, the dataset includes the measured results 108 that were generated by the hardware 106 for different hardware inputs.

### Training The Machine Learning Model

In certain embodiments, the simulation results 104 and the measured results 108 are used to train a machine learning model 110. In other embodiments, a bill of materials (BOM) data 114 that defines the circuit design is also used in the machine learning model 110. During training, the machine learning model 110 is trained to predict the errors in the simulation results 104 as compared to the measured results 109.

In one embodiment the bill of materials (BOM) includes the surface mount components, the values of the surface mount components, the base resistor values, the types and amount of power amplifiers, multi-chip module configurations, the type of die such as whether a silicon-on-insulator (SOI) die is used, and the type of included circuits, such as whether a low-dropout (LDO) regulator circuit is used.

Other inputs into the machine learning model 110 can include the implementation technology (PA-tech), which for example, can identify whether silicon germanium (SiGe) is used. Another input into the machine learning model 110 can include the foundry (PA-foun), or the type or process (PA_proc), or the substrate resistivity (PA_sub). The inputs into the machine learning model 110 can further include a unique identifier number to indicate a circuit topology us as an indentifier for the input matching network (IMN) topology (IMN_Top), interstage topology (INT_Top), or an identifier for an output matching network topology (OMN_top). Other inputs into the machine learning model 110 can include setup variables such a reference current, transistor sizing, operating voltage, operating frequency, operating mode such as WiFi and Bluetooth, and the power amplifier model used.

The machine learning model 110 may use any appropriate machine learning algorithm including by way of example, a gradient tree boosting, ensemble algorithm, a linear regression algorithm, a least absolute shrinkage and selection operator (LASSO) algorithm, a support vector regression (SVR) algorithm, random forest algorithms, or bayesian ridge regression algorithms to name a few. The training of the machine learning model 110 is typically performed after completion of multiple simulation runs by the simulation model 102 and multiple tests of the hardware 106.

The machine learning model 110 can be trained based on each of the measured results 108, for on combinations thereof. In certain embodiments, the machine learning model 110 is trained to augment the simulation results 104 associated with radio frequency circuits, augment simulation results 104 associated with power amplifier circuits, or augment simulation results 104 associated with an output matching network (OMN). The augmented simulation results 112 are provided as an output.

For example, one can train multiple machine learning models 110 that augment simulation results for different desired parameters. In one embodiment, a machine learning model 110 augments simulation results 104 for the simulation of dynamic error vector magnitude (EVM) performance. EVM parameters can include: EVM at 19 dBm output power, EVM at 17 dBm output power, EVM at 12 dBm output power, EVM at 17 dBm output power over 2:1 voltage standing wave ratio (VSWR), EVM at 19 dBm power over 2:1 voltage standing wave ratio (VSWR), or output power at −30 dB EVM.

Machine learning models 110 can also be train machine learning models 110 that augment simulation results for current-based parameters. In one embodiment, a machine learning model 110 augments simulation results 104 for the simulation of current at for example: multi-chip module (MCM) current at 19 dBm Output Power, multi-chip module (MCM) current at 17 dBm Output Power, multi-chip module (MCM) current at 12 dBm Output Power, or multi-chip module (MCM) current at −30 dB EVM.

A trained machine learning model 110 can also augment simulation scattering parameters, or S-parameters, such as S11, S12, S21, and S22 which is a transmission coefficient from port 2 to port 1, and S22. Still further, a trained machine learning model 110 can also augment simulation gain-based parameters such as gain at 19 dBm output power, gain at 17 dBm output power, or gain at 12 dBm output power to name a few. Yet further, a trained machine learning model 110 can also augment simulation adjacent channel power (ACP) results, Bluetooth basic data rate (BDR) results and enhanced data rate (EDR) results such as by way of example, BDR ACP at 22 dBm output power with a 2 MHz channel offset, BDR ACP at 22 dBm output power with a 3 MHz channel offset, EDR ACP at 15 dBm output power with a 2 MHz channel offset, EDR ACP at 15 dBm output power with a 3 MHz channel offset.

In addition, computer-executable code can be used to extract the simulation results and actual results from one or more datasets. Still further, computer-executable code can generate simulations corresponding to the measured results 108.

After training, the machine learning model 110 receives simulation results 104 and predicts the measured results 108 that one would measure from the hardware 106. This prediction of the measured results 108 augments the simulation results 104 without having to more accurately simulate the actual operation of the hardware 106.

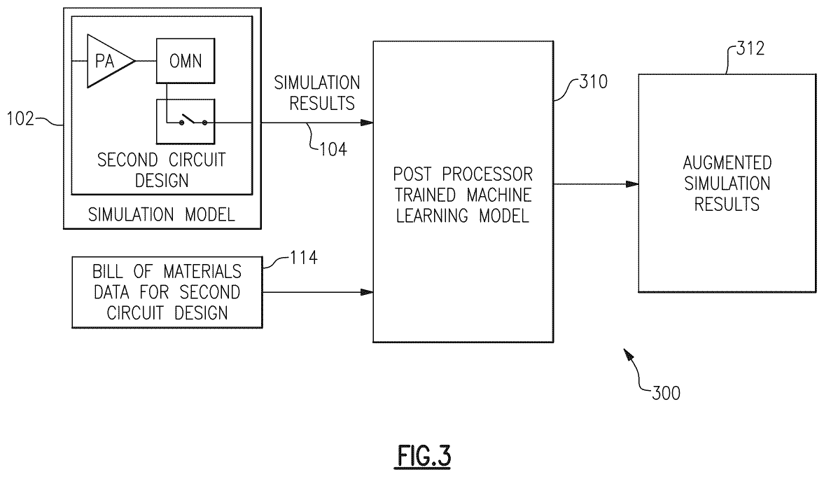

FIG. 2 illustrates another embodiment where the simulation results 102, the measured results 108, and/or the bill of materials data 114 are stored in a results dataset 200. The results dataset 200 includes and correlates both the simulation results 104 and the measured results 108. Furthermore, the results dataset 200 is subdivided in to a first portion called the training set 202 and a second portion called the test set 204.

The training set 202 includes a portion of the simulation results 104 and a portion of the measured results 108. The simulation results 104 and the measured results 108 in the training set 202 are used to train the machine learning model 110 as discussed above.

The test set 204 contains a different portion of the simulation results 104 and the measured results 108, and they are used to determine the accuracy of the machine learning model 110. After training the machine learning model 110 with the training set 202, the simulation results 104 in the test set 204 are applied in block 206 to the trained machine learning model 110. The trained machine learning model, in turn, predicts the measured results 108 in the test set 204 by augmenting the simulation results 104.

In block 208, the trained machine language model's predicted measured results are then compared to the measured results 108 in the test set 204. The difference between the machine language model's predicted measure results and the actual measured results 108 are then used to determine the accuracy of the trained machine language model 110. If the accuracy of the trained machine language model 110 is deemed to be insufficient, additional simulation results 104 and measurement results 108 are obtained to further train the machine learning model 110.

After sufficient training, the machine learning model 110 generates machine learning output that predicts the errors in the simulation results 104 generated by the simulation model 102 as compared to the measured results 108. The trained machine learning model 110 can then be used to augment future simulation results 104.

### Simulation Post-Processor Machine Learning Model

FIG. 3 depicts a system 300 that uses a simulation post-processor trained machine language model 310. In operation, the simulation model 102 generates simulation results 104 for a second circuit design that is different than the first circuit design. The simulation results 104 associated with the simulation of the second circuit design are input into a post-processor trained machine language model 310 that has been trained as discussed above. In some embodiments, the bill of materials data for the second circuit design is also inputted into the post-processor trained machine learning model 310.

The post processor trained machine learning model processes the simulation results 104 for the second circuit design and/or the bill of materials data 114 for the second circuit design and augments the simulation results 104 to create augmented simulation results 312. The augmented simulation results 312 improve the accuracy of the simulation results without having to modify, backfit or change the simulation model 102. In other words, the post-processor trained machine learning model 310 that is trained with simulated results 104 and measured results 108, is used to generate augmented simulation results 312 for a second circuit design that this different than the first circuit design without need to backfit of change the simulation model 102.

Changing the parameters of other aspects of the simulation model 102 is time consuming and requires lab-based tuning with many variants. Although this leads to simulation results that more closely match real world results, adding the parasitic circuit offsets or changing other parameters is often by trial and error, with a manual, subjective approach that requires design time and added simulation time. Furthermore, even when a designer has improved simulator accuracy with the parasitic circuit offsets, the adaptions are not likely to predict future results over a wide range of operating conditions.

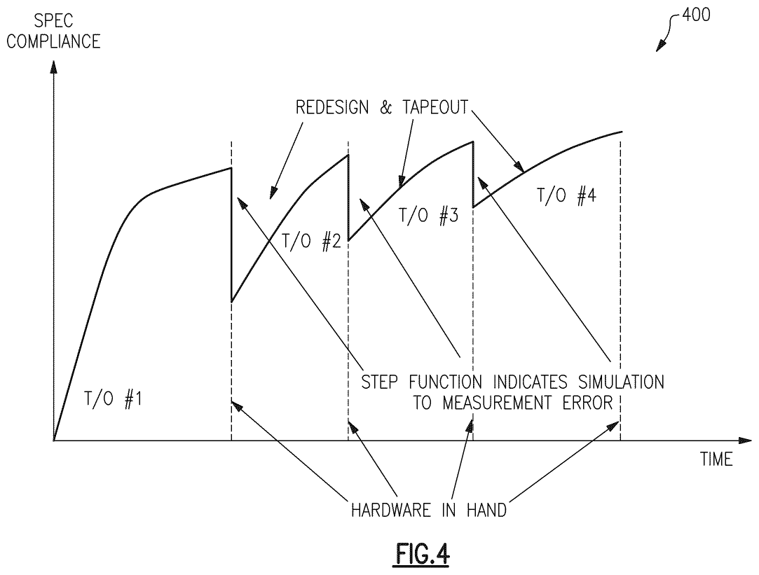

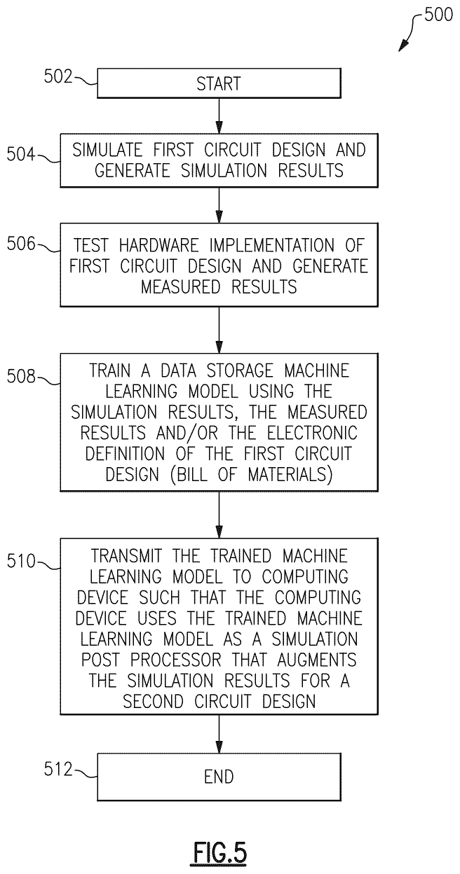

For example, FIG. 4 illustrates the process 400 of generating multiple hardware prototypes for a circuit design. The goal is to create a circuit design that complies with desired specifications. A designer creates a first hardware prototype called a tape out 1 (T/O #1). Unfortunately due to differences between simulation and measurement errors, TO #1 does comply with the desired specifications and needs to be redesigned. This cycle is in turn repeated for T/0#2, T/0#3, and T/O#4 until the circuit design complies with the desired specifications.

The post-processor trained machine learning model 310 improves this design process by generating augmented simulation results 312 that more accurately reflect the measured results 108 from T/O #1. Although the circuit design for TO #1 is different than the circuit design for T/O #2, the augmented simulation results 312 for T/0#2, are closer to the measured results 108 than the simulation results 104.

Thus, certain embodiments of the invention allow a designer to continue to use the simulation model 102 without needing to adjust, backfit or modify the simulation model 102. This can significantly increase design efficiency. Instead of using the post-processor trained machine learning model 310 to change the simulation model 102, the post-processor trained machine learning model 310 is used as a post processor that augments the simulation model 102.

In other words, the post-processor trained machine learning model 310 is trained with simulation results 104 and measured results 108 associated with a first circuit design. A designer then creates a second circuit design that is different than the first circuit design.

The designer simulates the second circuit design with the simulation model 102 to generate simulation results 104 for the second circuit design. The simulation results 104 are then input into the post-processor machine learning model 310 which in turn generates the augmented simulation results 312 for the second circuit design.

Although the second circuit design is different than the first circuit design used to create the post-processor machine learning model 310, the post-processor machine learning model 310 generates augmented simulation results that are generally more accurate than if the designer had attempted to backfit or modify the simulation model 102. Thus, the post-processor machine language model learns the error in simulation introduced by structures and/or other effects that are not captured by the simulation model.

In certain embodiments, the machine learning model augments or reduces errors in the simulation results such as by way of example, electromagnetic block interaction errors, coding errors, thermal modeling errors, surface mount component (SMT) modeling errors, multi-chip module (MCM) modeling errors in the simulation results, mixed-signal integrated circuit errors in the simulation results, process variation errors, and harmonic balance errors.

The post-processor trained machine learning model 310 is can also be periodically retrained. That is, when a hardware implementation of the second circuit design is tested, the measured results 108 from the second hardware can be used to retrain the post-processor machine learning model 110, without having to adjust the simulation model 102.

### Method Augmenting Simulation Results With A Post Processor Machine Learning Model

FIG. 5 depicts some salient operations of a method 500 for training a post-processor machine learning model according to an illustrative embodiment of the invention. The method 500 may be performed by one or more computer processors having computer-executable instructions. The method 500 starts at block 502.

At block 504, the simulation model 102 simulates a first circuit design and generates the simulation results 104. The simulation model 102 generates simulation results 104 based on the definition of the first circuit design and the simulation values or parameters. The simulation results 104 may include any simulated event or other statistics generated by the simulation model 102. By way of example, the simulation results 104 include a dataset of generated values that may include power levels, real and imaginary values, OMN loss, EVM performance, current, and power gain to name a few. Typically when simulating a circuit design, the inputs are varied to obtain a range of simulation results 104.

The simulation results 104 are stored in a results dataset 200 that correlates the simulation results 104 with the simulation inputs used to generate the simulation results 104. Thus, the results dataset 200 indicates the simulation results 104 that were generated by the simulation model 102 for different simulation values.

At block 506, a physical implementation of the first circuit design hardware 106 is built and tested. During testing, inputs are applied to the first circuit design hardware 106, and the outputs of the first hardware 106 are measured to generate the measured results 108. The measured results 108 represent the performance of the first circuit design hardware 106 in response to various inputs.

In measuring the first circuit design hardware 106, the user may use test probes, oscilloscopes and other test measurement equipment to make actual physical connections to one or more test points on the circuit design hardware 106 such as inputs, output pins, tracks, or individual components to acquire actual data, waveforms, or measurements from the circuit design hardware 106.

The measured results 108 are stored in the results dataset 200 that correlates the measured results 108 with the inputs used to generate the measured results 108. Thus, the dataset indicates the measured results 108 that were generated by the first circuit design hardware 106 for different inputs.

At block 508, the machine learning model 110 is trained using the simulation results 104 and the measured results 108. In some embodiments, the definition or net list of the circuit design (bill of materials) data 114 is also used to train the machine learning model 110. During training, the machine learning model 110 is trained to predict the errors in the simulation results 104 generated by the simulation model 102 as compared to the measured results 108 generated by the hardware 106.

The machine learning model 110 may use any appropriate machine learning algorithm including by way of example, a gradient tree boosting, ensemble algorithm, a linear regression algorithm, a least absolute shrinkage and selection operator (LASSO) algorithm, a support vector regression (SVR) algorithm, random forest algorithms, or bayesian ridge regression algorithms to name a few.

This process can also create multiple machine learning models 110 that focus on different aspects of the measured results. For example, the measured results 108 may be used to train one machine learning model 110 to augment simulation results associated with radio frequency circuits, while another machine learning model may be trained to augment simulation results associated with power amplifier circuits, or augment simulation results associated with an output matching network (OMN) model. Indeed, the machine learning model 100 can be trained to focus on any measured result 108 generated by the hardware 106, or combinations thereof.

At block 510, the post-processor trained machine learning model 310 is transmitted to a computing device such that the computing device uses the trained machine learning model 310 as a simulation post processor that augments the simulation results 104 for a second circuit design that is different than the first circuit design.

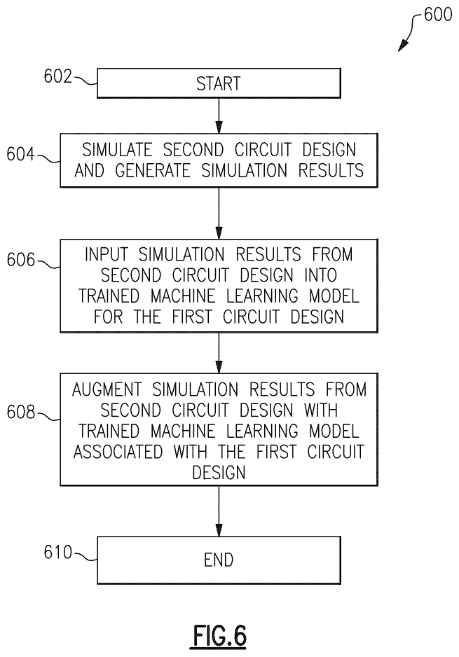

FIG. 6 depicts some salient operations of a method 600 for using the post-processor trained learning model 310 as a simulation post processor. The method 600 starts at block 602.

At block 604, the simulation model 102 simulates a second circuit design and generates the simulation results 104. The simulation model 102 generates simulation results 104 based on the definition of the second circuit design and the simulation values. The simulation results 104 may for the second circuit design, include any simulated event or other statistics generated by the simulation model 102.

At block 606, the simulation results 104 associated with the second circuit design are then input into the post-processor machine learning model 310 which in turn generates augmented simulation results 312 for the second circuit design.

Although the second circuit design is different than the first circuit design used to create the post-processor machine learning model 310, the post-processor machine learning model 310 generates augmented simulation results 312 that are generally more accurate than if the designer had attempted to backfit or modify the simulation model 102. Thus, the post-processor machine language model learns the error in simulation introduced by structures and/or other effects that are not captured by the simulation model.

Thus, a designer may use the simulation model 102 to simulate a second design circuit, predict the error in the simulation results 104 with the post-processor trained machine learning model 310, and adjust the simulation results 104 based on the predicted error to output the augmented simulation results 312. This approach can significantly improve design efficiencies and reduce design prototyping, and reduce the time associated with backfitting the simulator.

The post-processor trained machine learning model 310 is can also be periodically retrained. That is, when a hardware implementation of the second circuit design is tested, the measured results 108 for the second circuit can be used to retrain the post-processor trained machine learning model 310, without having to adjust the simulation model 102.

### Example Embodiments

In one embodiment, the first circuit is a first power amplifier circuit, and the second circuit is a dual-mode power amplifier circuit. The second circuit design is a second version of a modified the dual mode.

Industry demands for reduced power amplifier (PA) footprint can introduce significant challenges for front end module (FEM) suppliers, particularly to maintain the high levels of PA performance in a reduced FEM size. Wireless Local Area Network (WLAN) and Bluetooth standards share overlapping frequency bands at 2.45 GHz, but have different PA power and linearity specifications. Attempts have been made to use a single PA chain for Wi-Fi and Bluetooth. However, significant performance degradation was introduced in comparison to utilizing a larger dual PA solution.

Aspects of this disclosure provide augmented simulation results 312 where high performance is maintained in a single multi-mode PA chain. In this embodiment, radio frequency (RF) performance can be preserved relative to a significantly larger dual PA equivalent. The multi-mode PA chain can be a dual mode PA chain. The multi-mode PA chain can support the Bluetooth and Wi Fi standards. Technical solutions disclosed herein involve reconfiguring the PA for different modes and using a split output matching network (OMN). These features can be implemented together with enhanced and/or optimized device sizing and enhanced and/or optimized load line impedance with relatively minimal matching losses. With such technical solutions, two PA modes can achieve higher performance comparable to a dual PA equivalent. At the same time, single dual-mode PA chains disclosed herein can achieve a greater than 50% chip size and cost reduction relative to dual PA equivalents.

Products have typically used separate Bluetooth and Wi-Fi power amplifiers. An identical PA chain for both Wi-Fi and Bluetooth modes has been utilized and exploited dual registers to store independent reference current settings that provide independently optimized bias settings in both modes. However, as such solution uses an identical PA chain in both modes, the lower power Bluetooth mode exhibits high current consumption, as the PA is oversized relative to its specification.

To achieve performance similar to separate Wi-Fi and Bluetooth PA solutions, this disclosure provides technical solutions that can use registers to optimize bias settings in a plurality of modes and also include addition features to preserve high performance and to meet customer specifications in each of the modes.

Auxiliary (AUX) power amplifier transistor shutdown, or device de-biasing, in a PA output stage can be implemented to effectively resize the PA devices. This can allow accurate control of the output power and current consumption of the PA, specific to the standard that the PA is operating in.

A split OMN architecture can be implemented that incorporates load line switching via a switched capacitor. The switch and the capacitor can be on a silicon-on-insulator (SOI) die. Switching can introduce output matching network loss that can degrade performance. A single switch can be used to mitigate the impact of switching on output matching network loss. Including the switch at the load end of the OMN together with a surface mount technology (SMT) series inductor can allow a relatively large range of Wi-Fi load line control around the Smith Chart with a relatively minor impact on the real part of the Bluetooth load line impedance. The switching capacitor being at or near an antenna port can allows an impedance trajectory that moves from a highly inductive Bluetooth load line (e.g., due to parasitic off-state AUX devices) towards a real but lower load line in Wi-Fi mode. The Bluetooth load line impedance can be tuned with a first OMN section and a second OMN section can be used to tune the Wi-Fi mode load line impedance.

Gain in a plurality of modes can be controlled by gain stage periphery switching. For higher gain, auxiliary power amplifier transistors can be included in the gain stage. In a lower power mode with lower gain, a proportion of the gain stage can be shut down to meet a desired lower gain operation. This can involve deactivating the auxiliary power amplifier transistors of the gain stage.

Technology described herein can achieve reduced current consumption in a Bluetooth mode by approximately 80% relative to designs that adjust reference current between modes and otherwise include the same power amplifier signal path for Bluetooth and Wi-Fi modes. For Bluetooth application, current consumption is a significant technical specification. Optimized device sizing, load lines and reference current control (e.g., via registers), for a plurality of modes, can achieve tight gain control over temperature, increased linearity, reduced out of band emissions (DOBE), or any suitable combination thereof. Tuning with a split OMN architecture can contribute to quicker time to market in comparison to tuning a non-partitioned OMN. Architectures disclosed herein can achieve high performance for both Bluetooth and Wi-Fi in a small footprint.

Multi-mode power amplifier system embodiments will be now be discussed with reference to the figures.

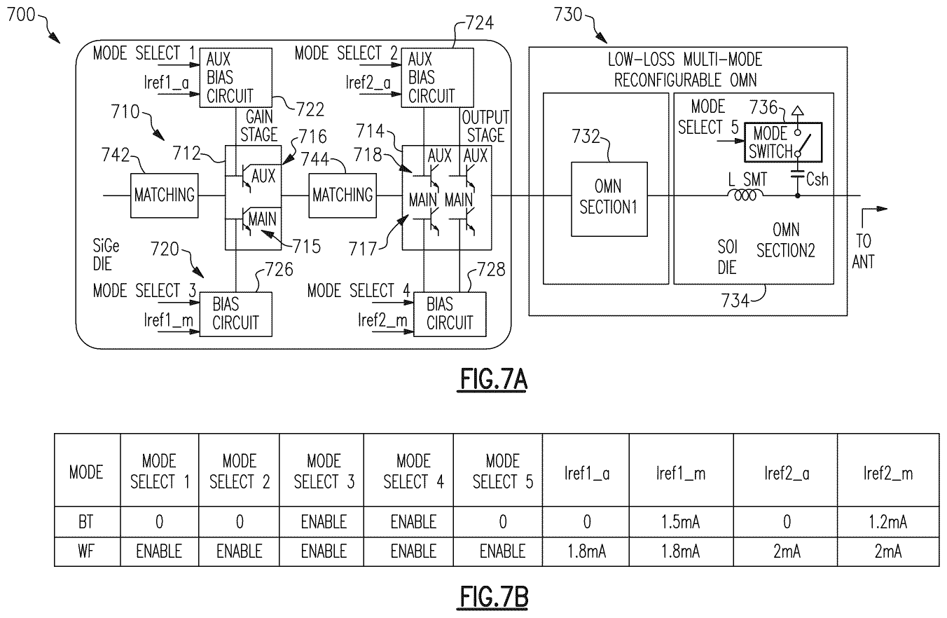

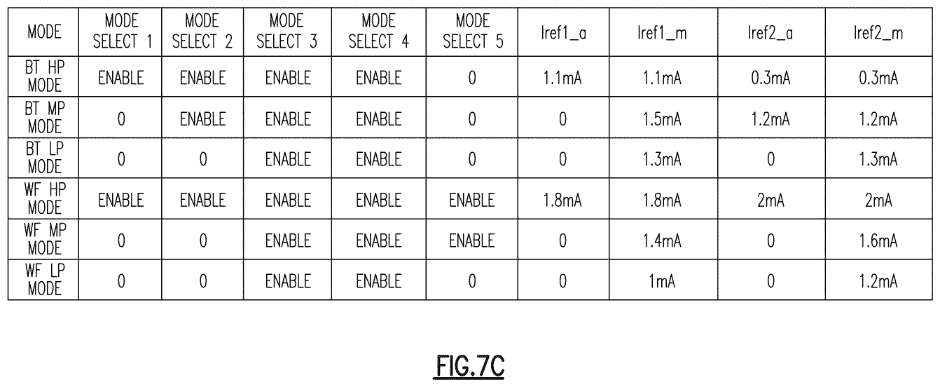

FIG. 7A is a schematic diagram of an example multi-mode power amplifier system 700 according to an embodiment. As illustrated, the multi-mode power amplifier system 700 includes a power amplifier 710, a bias circuit 720, and an output matching network 730. For different modes of operation, the multi-mode power amplifier system 700 can adjust reference current for the power amplifier 710, selectively active or deactivate one or more auxiliary power amplifier transistors, adjust an output matching impedance for the power amplifier 710, or any suitable combination thereof.

The multi-mode power amplifier system 700 can operate in at least two modes. For example, the multi-mode power amplifier system 700 can operate in 2 modes corresponding to FIG. 7B. As another example, the multi-mode power amplifier system 700 can operate in 6 modes corresponding to FIG. 7C. The at least 2 modes can relate to different radio access technologies. The at least 2 modes can include a WLAN mode and a WPAN mode. For instance, the WLAN mode can be a Wi-Fi mode and the WPAN mode can be a Bluetooth mode. The at least two modes can be different power modes, such as low power (LP), medium power (MP), and high power (HP). The at least two modes can include modes that are a combination of a standard for wireless communication and power level. For instance, the modes can include a Wi-Fi LP mode, a Wi-Fi MP mode, a Wi-Fi HP mode, a Bluetooth LP mode, a Bluetooth MP mode, and a Bluetooth HP. The at least two modes can include modes associated with different linearity specifications, coexistence and non coexistence modes, the like, or any suitable combination thereof.

An input matching network 742 and an interstage matching network 744 can be included for the power amplifier 710. The illustrated power amplifier 710 includes a gain stage 712 and an output stage 714. In some other applications, a power amplifier can include three or more stages.

The gain stage 712 can set or impact the gain of the power amplifier 710. The gain stage 712 can include a main power amplifier transistor 715 and an auxiliary power amplifier transistor 716. The main power amplifier transistor 715 and/or the auxiliary power amplifier transistor 716 can each be implemented by transistor arrays. These transistors can be silicon germanium transistors. The main power amplifier transistor 715 and the auxiliary power amplifier transistor 716 of the gain stage 712 can have any suitable ratio relative to each other for a particular application.

The output stage 714 can include a main power amplifier transistor 717 and an auxiliary power amplifier transistor 718. The main power amplifier transistor 717 and/or the auxiliary power amplifier transistor 718 can each be implemented by transistor arrays. These transistors can be silicon germanium transistors. The main power amplifier transistor 717 and the auxiliary power amplifier transistor of the output stage can have any suitable ratio relative to each other for a particular application. The transistors of the output stage 714 can be larger than the transistor of the gain stage 712.

The bias circuit 720 can a provide reference current to power amplifier transistors. The references currents can be different for the gain stage 712 and the output stage 714 during the same mode of operation. The bias circuit 720 can include memory elements that store values for reference current settings that provide bias settings for each mode. The memory elements can include registers. Alternatively or additionally, the memory elements can include fuses. The settings stored in the memory elements of the bias circuit 720 can account for a power mode and a temperature profile of the power amplifier 710, for example. The bias circuit 720 can include bias circuitry 722, 724, 726, and 728 for individual PA transistors or transistor arrays.

The bias circuit 720 can select a mode of operation. The bias circuit 720 can disable the auxiliary power amplifier transistor 716 of the gain stage 712 based on a value of a mode select signal Model Select 1 provided to the bias circuit 720. Alternatively or additionally, the bias circuit 720 can disable the auxiliary power amplifier transistor 718 of the output stage 714 based on a value of a mode select signal Mode Select 2 provided to the bias circuit 720.

The output matching network 730 is connected to an output of the power amplifier 710. The output matching network 730 can include a first section 732 and a second section 734 that is connected to the output of the power amplifier 710 by way of the first section 732. The first section 732 can be tuned for performance in one mode of operation. The first section 732 can include passive impedance elements, such as one or more capacitors and one or more inductors, arranged in any suitable circuit topology and having any suitable impedance values for a particular application.

The second section 734 can adjust an output matching impedance for the power amplifier 710 for a second mode relative to the first mode. As illustrated in FIG. 7A, the second section 734 includes a series SMT inductor L SMT and a shunt capacitor Csh in series with a switch 736. The switch 736 can switch in the capacitor Csh in the first mode and switch out the capacitor Csh in the second mode such that the impedance of the capacitor Csh is included in the output matching impedance in the first mode and not in the second mode. By adjusting the output matching impedance, the second section 734 can tune the output impedance for a mode of operation. For example, the first section 732 can tune output matching impedance for a Bluetooth mode and the second section 734 can tune output matching impedance for a Wi-Fi mode.

The power amplifier 710 can be on a silicon germanium die. The bias circuit 720 can also be on the silicon germanium die. The switch 736 can be on a semiconductor on insulator die, such as a SOI die. The capacitor Csh can also be on the SOI die. The first section 732 of the OMN 730 can include SMT passive impedance elements. The first section 732 of the OMN 730 can alternatively or additionally include one or more passive impedance elements on the silicon germanium die, one or more passive impedance elements on the SOI die, or one or more passive impedance elements on the silicon germanium die and one or more passive impedance elements on the SOI die.

FIG. 7B is a table of signal values for the multi-mode power amplifier system 700 of FIG. 7A for two modes according to an embodiment. FIG. 7B will be discussed with reference to the multi-mode power amplifier system 700 of FIG. 7A for illustrative purposes. Any suitable principles and advantages discussed with reference to FIG. 7B can be implemented in any other suitable power amplifier system. The two modes are a Wi-Fi mode and a Bluetooth mode in FIG. 7B. The auxiliary power amplifier transistors 716 and 718 can be deactivated and reference currents can be reduced for the Bluetooth mode relative to the Wi Fi mode. The output matching impedance for the power amplifier 710 can be adjusted such that the capacitor Csh is switched out for the Bluetooth mode and switched in for the Wi Fi mode.

In a Wi-Fi mode, mode select signals Mode Select 1 to Mode Select 4 can enable the main power amplifier transistor 715 and the auxiliary power amplifier transistor 716 of the gain stage 712 and also enable the main power amplifier transistor 717 and the auxiliary power amplifier transistor 718 of the output stage 714. A mode select signal Mode Select 5 can turn on the switch 736 of the OMN 730 to switch in the capacitor Csh for the Wi-Fi mode.

In a Bluetooth mode, the model select signals Mode Select 1 to Mode Select 4 can enable the main power amplifier transistor 715 of the gain stage 712 and the main power amplifier transistor 717 of the output stage 714 while disabling the auxiliary power amplifier transistor 716 of the gain stage 712 and the auxiliary power amplifier transistor 718 of the output stage 714. The bias circuit 720 (e.g., bias circuitry 726 and 728) can reduce the reference currents Iref1_m and Iref2_m provided to respective main power amplifier transistors 715 and 717 for the Bluetooth stage relative to the Wi-Fi stage. FIG. 7B provides example reductions in reference current values. The bias circuit 720 (e.g., bias circuitry 722 and 724) can reduce the reference currents Iref1_a and Iref2_a to zero or approximately zero for the auxiliary power amplifier transistors 716 and 718 for the Bluetooth mode. A mode select signal Mode Select 5 can turn off the switch 736 of the OMN 730 to switch pit the capacitor for the Bluetooth mode.

FIG. 7C is a table of signal values for the multi-mode power amplifier system 700 of FIG. 7A for six modes according to an embodiment. FIG. 7C will be discussed with reference to the multi-mode power amplifier system 700 of FIG. 7A for illustrative purposes. Any suitable principles and advantages discussed with reference to FIG. 7C can be implemented in any other suitable power amplifier system. The six modes are a LP Wi-Fi mode, a MP Wi-Fi mode, a HP Wi-Fi mode, a LP Bluetooth mode, a MP Bluetooth mode, and a HP Bluetooth mode in FIG. 7C.

The auxiliary power amplifier transistor 716 of the gain stage 712 can be activated for the Wi-Fi HP mode and the Bluetooth HP mode. The auxiliary power amplifier transistor 716 of the gain stage 712 can be deactivated for the other modes of FIG. 7C.

The auxiliary power amplifier transistor 718 of the output stage 714 can be activated for the Wi-Fi HP mode, the Bluetooth MP mode, and the Bluetooth HP mode. The auxiliary power amplifier transistor 718 of the output stage 714 can be deactivated for the other modes of FIG. 7C.

FIG. 7C provides example reference current values for the various modes. The reference current Iref1_a for the auxiliary power amplifier transistor 716 of the gain stage 712 can be zero or approximately zero when deactivated. The reference current Iref2_a for the auxiliary power amplifier transistor 718 of the output stage 714 can be zero or approximately zero when deactivated.

The capacitor Csh can be switched in for the output matching impedance for the Wi Fi HP mode and the Wi-Fi MP modes. The capacitor Csh can be switched out and not included in the output matching impedance for the other modes of FIG. 7C.

Such circuitry is difficult to simulate accurately. Furthermore, simulations can consume significant computing power and take large amounts of time to run. Using an embodiment of the invention, the multi-mode power amplifier system 700 is designed and the net list of bill of materials is provided to a simulation model 102.

The simulation model 102 simulates the multi-mode power amplifier system 177 a first circuit design and generates the simulation results 104. The simulation model 102 generates simulation results 104 based on the definition of the multi-mode power amplifier system 700 and the simulation values or parameters. By way of example, the simulation results 104 include a dataset of generated values that may include power levels, real and imaginary values, OMN loss, EVM performance, current, and power gain to name a few. Typically when simulating a circuit design, the inputs are varied to obtain a range of simulation results 104.

In one embodiment the bill of materials (BOM) provided to the machine learning module 110 includes the surface mount components, the values of the surface mount components, the base resistor values, the types and amount of power amplifiers, multi-chip module configurations, the type of die such as whether a silicon-on-insulator (SOI) die is used, and the type of included circuits, such as whether a low-dropout (LDO) regulator circuit is used.

Other inputs into the machine learning model 110 can include the implementation technology (PA-tech), which for example, can identify whether silicon germanium (SiGe) is used. Another input into the machine learning model 110 can include the foundry (PA-foun), or the type or process (PA_proc), or the substrate resistivity (PA_sub). The inputs into the machine learning model 110 can further include a unique identifier number to indicate a circuit topology us as an indentifier for the input matching network (IMN) topology (IMN_Top), interstage topology (INT_Top), or an identifier for an output matching network topology (OMN_top). Other inputs into the machine learning model 110 can include setup variables such a reference current, transistor sizing, operating voltage, operating frequency, operating mode such as WiFi and Bluetooth, and the power amplifier model used.

The simulation results 104 are stored in a results dataset 200 that correlates the simulation results 104 with the simulation inputs used to generate the simulation results 104. Thus, the results dataset 200 indicates the simulation results 104 that were generated by the simulation model 102 for different simulation values.

A physical implementation of the multi-mode power amplifier system 700 is built and tested. During testing, inputs are applied to the physical implementation of the multi-mode power amplifier system 700, and the outputs of the physical implementation of the multi-mode power amplifier system 700 are measured to generate the measured results 108. The measured results 108 represent the performance of the multi-mode power amplifier system 700 in response to various inputs.

The measured results 108 may include any measurable output of the hardware 106, including, but not limited to power levels, voltage levels, EVM performance, current, and power gain to name a few. For example, the measured results 108 may the termination load or output load often referred to as the Zload. In some embodiments, the Zload can include an antenna impedance. The measured results 108 may also include the measurement test temperature.

Another measured result 108 can include a variety of test types such as large signal test, small signal test, or scattering parameters test. Scattering parameters, or S-parameters are defined in terms of incident and reflected traveling waves and typically describe the input-output relationship between two ports or terminals. The S-parameters may include S11 which is a reflection coefficient for port 1, S22 which is a reflection coefficients for port 2, S12 which is a transmission coefficient from port 2 to port 1, and S21 is a transmission coefficient from port 1 to port 2. S-parameters are usually specified in decibels (dB).

Another measured result 108 can include modulation type such as modulation types defined by the Modulation Coding Scheme (MCS) index and the Enhanced Data Rate (EDR). The Modulation Coding Scheme (MCS) index is an existing industry metric based on several parameters of a Wi-Fi connection between a client device and a wireless access point, including data rate, channel width, and the number of antennas or spatial streams in the device. The Enhanced Data Rate (EDR) is an industry standard modulation scheme associated with the Bluetooth standard.

Another measured result 108 can include the duty cycle of a waveform. Yet another measured result 108 can include a waveform burst length (Burst_Len). Still another measure result 108 can include the location and testbench used for hardware measurements (Test_site).

The measured results 108 are stored in the results dataset 200 that correlates the measured results 108 with the inputs used to generate the measured results 108. Thus, the dataset indicates the measured results 108 that were generated by the multi-mode power amplifier system 700 for different inputs.

The machine learning model 110 is trained using the simulation results 104 and the measured results 108. In some embodiments, the electronic definition of the circuit design (bill of materials) data 114 is also used to train the machine learning model 110. During training, the machine learning model 110 is trained to predict the errors in the simulation results 104 generated by the simulation model 102 as compared to the measured results 108 generated by the hardware 106.

In this embodiment, machine learning model 110 uses a gradient tree boosting, ensemble algorithm, but other algorithms as discussed above can be used. This process can also create multiple machine learning models 110 that focus on different aspects of the measured results.

The machine learning model 110 can be trained based on each of the measured results 108, for on combinations thereof. In certain embodiments, the machine learning model 110 is trained to augment the simulation results 104 associated with radio frequency circuits, augment simulation results 104 associated with power amplifier circuits, or augment simulation results 104 associated with an output matching network (OMN). The augmented simulation results 112 are provided as an output.

For example, one can train multiple machine learning models 110 that augment simulation results for different desired parameters. In one embodiment, a machine learning model 110 augments simulation results 104 for the simulation of dynamic error vector magnitude (EVM) performance. EVM parameters can include: EVM at 19 dBm output power, EVM at 17 dBm output power, EVM at 12 dBm output power, EVM at 17 dBm output power over 2:1 voltage standing wave ratio (VSWR), EVM at 19 dBm power over 2:1 voltage standing wave ratio (VSWR), or output power at −30 dB EVM.

Machine learning models 110 can also be train machine learning models 110 that augment simulation results for current-based parameters. In one embodiment, a machine learning model 110 augments simulation results 104 for the simulation of current at for example: multi-chip module (MCM) current at 19 dBm Output Power, multi-chip module (MCM) current at 17 dBm Output Power, multi-chip module (MCM) current at 12 dBm Output Power, or multi-chip module (MCM) current at −30 dB EVM.

A trained machine learning model 110 can also augment simulation scattering parameters, or S-parameters, such as S11, S12, S21, and S22 which is a transmission coefficient from port 2 to port 1, and S22. Still further, a trained machine learning model 110 can also augment simulation gain-based parameters such as gain at 19 dBm output power, gain at 17 dBm output power, or gain at 12 dBm output power to name a few. Yet further, a trained machine learning model 110 can also augment simulation adjacent channel power (ACP) results, Bluetooth basic data rate (BDR) results and enhanced data rate (EDR) results such as by way of example, BDR ACP at 22 dBm output power with a 2 MHz channel offset, BDR ACP at 22 dBm output power with a 3 MHz channel offset, EDR ACP at 15 dBm output power with a 2 MHz channel offset, EDR ACP at 15 dBm output power with a 3 MHz channel offset.

At block 510, the post-processor trained machine learning model 310 is transmitted to a computing device such that the computing device uses the post-processor trained machine learning model 310 as a simulation post processor that augments the simulation results 104 for a second circuit design (discussed below) that is different than the multi-mode power amplifier system 700.

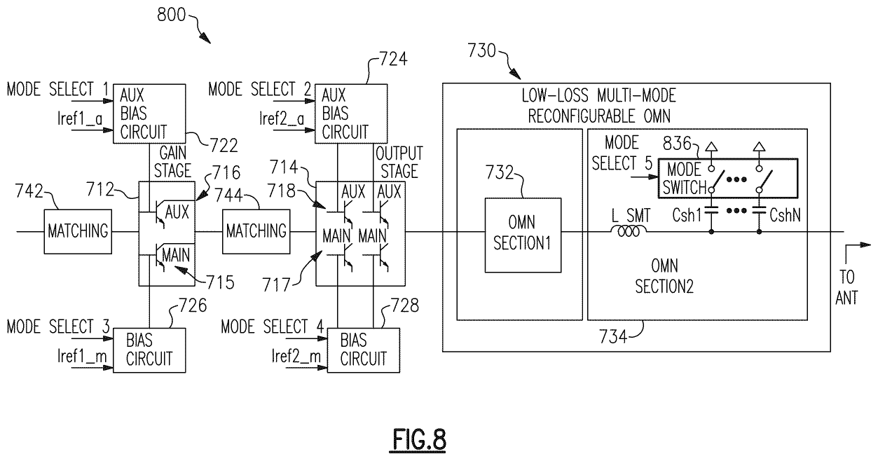

FIG. 8 is a schematic diagram of a second multi-mode power amplifier system 800 with adjustable output matching impedance according to an embodiment. The multi-mode power amplifier system 800 is like the multi-mode power amplifier system 700 of FIG. 7A, except that the multi-mode power amplifier system 800 includes an array of switches 836 and capacitors Csh1 to CshN instead of the switch 736 and capacitor Csh. An array of switches 836 and capacitors Csh1 to CshN can provide more tunability of the output matching impedance than a single switch and single capacitor. This additional tunability can be post manufacture. This can advantageously allow for tuning for different applications post manufacture and/or account for process variations or other issues introduced during manufacture.

In different modes of operation, a different number of capacitors Csh1 to CshN can be included in the output matching impedance using the array of switches 836. For instance, in one mode of operation all of the capacitors Csh1 to CshN can be switched out of the output matching impedance and one or more of the capacitors Csh1 to CshN can be switched in for another mode of operation. Alternatively, or additionally, some of the capacitors Csh1 to CshN can be switched in for a mode of operation and at least one different capacitor Csh1 to CshN can be switched in for another mode of operation.

Any other suitable circuit elements can be used to adjust the output matching impedance. One or more series capacitors, one or more series inductors, one or more shunt inductors, or any suitable combination thereof can be used to adjust an output matching impedance for a power amplifier. Such circuit elements can be arranged in any suitable circuit topology for a particular application. One or more switches can be used to adjust the output matching impedance. In some instances, the output matching impedance can be adjusted without using a switch. For example, a voltage applied to a varactor can be adjusted to adjust the output matching impedance.

In this example, the simulation model 102 simulates the multi-mode power amplifier system 800 with the array of switches 836 using the net list or bill of materials for multi-mode power amplifier system 800. The simulator generates the simulation results 104 multi-mode power amplifier system 800 that includes the array of switches 836.

At block 606, the simulation results 104 associated with the multi-mode power amplifier system 800 that includes the array of switches 836 are then input into the post-processor machine learning model 310 which in turn generates augmented simulation results 312 the multi-mode power amplifier system 800.

Although the multi-mode power amplifier system 800 is different than the multi-mode power amplifier system 700 in that the array of switches 836 is different than the switch 736, the post-processor machine learning model 310 generates augmented simulation results that are generally more accurate than if the designer had attempted to backfit or modify the simulation model 102. Thus, the post-processor machine language model learns the error in simulation introduced by structures in the multi-mode power amplifier system 700 that are not captured by the simulation model.

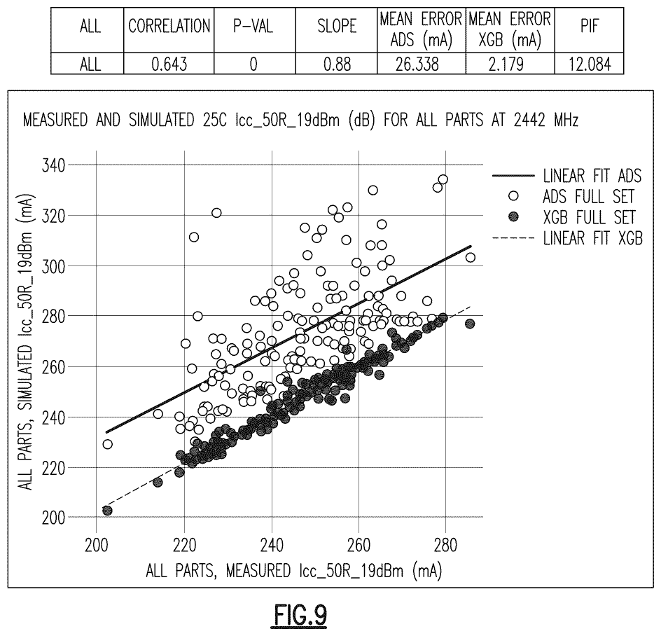

FIG. 9 illustrates an exemplary scatter plot 1000 that compares augmented simulation results associate with the dual-mode power amplifier system 800 with simulation results that have not been augmented. The scatter plot 100 compares simulated current results 102 on the y axis with measured current results on the x axis.

The augmented simulated results were generated with a trained machine learning module using gradient boosted threes which is referred to as “XGB.” The XGB values in the scatter plot 1000 are in blue and the linear fit line for the XGB values is in blue. The Advanced Design System (ADS) simulation values are illustrated in grey, while the linear fit of the ADS simulation values is shown in the red line.

The scatter plot 1000 illustrates that the augmented XGB values reduce the errors in the simulated results when compared to the simulated results that have not been augmented.

### Terminology

Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Unless the context clearly requires otherwise, throughout the description and the claims, the words “comprise,” “comprising,” and the like are to be construed in an inclusive sense, as opposed to an exclusive or exhaustive sense, i.e., in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number may also include the plural or singular number respectively. The word “or” in reference to a list of two or more items, covers all of the following interpretations of the word: any one of the items in the list, all of the items in the list, and any combination of the items in the list. Likewise, the term “and/or” in reference to a list of two or more items, covers all of the following interpretations of the word: any one of the items in the list, all of the items in the list, and any combination of the items in the list.

In some embodiments, certain operations, acts, events, or functions of any of the algorithms described herein can be performed in a different sequence, can be added, merged, or left out altogether (e.g., not all are necessary for the practice of the algorithms). In certain embodiments, operations, acts, functions, or events can be performed concurrently, e.g., through multi-threaded processing, interrupt processing, or multiple processors or processor cores or on other parallel architectures, rather than sequentially.

Systems and modules described herein may comprise software, firmware, hardware, or any combination(s) of software, firmware, or hardware suitable for the purposes described. Software and other modules may reside and execute on servers, workstations, personal computers, computerized tablets, PDAs, and other computing devices suitable for the purposes described herein. Software and other modules may be accessible via local computer memory, via a network, via a browser, or via other means suitable for the purposes described herein. Data structures described herein may comprise computer files, variables, programming arrays, programming structures, or any electronic information storage schemes or methods, or any combinations thereof, suitable for the purposes described herein. User interface elements described herein may comprise elements from graphical user interfaces, interactive voice response, command line interfaces, and other suitable interfaces.

Further, processing of the various components of the illustrated systems can be distributed across multiple machines, networks, and other computing resources. Two or more components of a system can be combined into fewer components. Various components of the illustrated systems can be implemented in one or more virtual machines, rather than in dedicated computer hardware systems and/or computing devices. Likewise, the data repositories shown can represent physical and/or logical data storage, including, e.g., storage area networks or other distributed storage systems. Moreover, in some embodiments the connections between the components shown represent possible paths of data flow, rather than actual connections between hardware. While some examples of possible connections are shown, any of the subset of the components shown can communicate with any other subset of components in various implementations.

Embodiments are also described above with reference to flow chart illustrations and/or block diagrams of methods, apparatus (systems) and computer program products. Each block of the flow chart illustrations and/or block diagrams, and combinations of blocks in the flow chart illustrations and/or block diagrams, may be implemented by computer program instructions. Such instructions may be provided to a processor of a general purpose computer, special purpose computer, specially-equipped computer (e.g., comprising a high-performance database server, a graphics subsystem, etc.) or other programmable data processing apparatus to produce a machine, such that the instructions, which execute via the processor(s) of the computer or other programmable data processing apparatus, create means for implementing the acts specified in the flow chart and/or block diagram block or blocks. These computer program instructions may also be stored in a non-transitory computer-readable memory that can direct a computer or other programmable data processing apparatus to operate in a particular manner, such that the instructions stored in the computer-readable memory produce an article of manufacture including instruction means which implement the acts specified in the flow chart and/or block diagram block or blocks. The computer program instructions may also be loaded to a computing device or other programmable data processing apparatus to cause operations to be performed on the computing device or other programmable apparatus to produce a computer implemented process such that the instructions which execute on the computing device or other programmable apparatus provide steps for implementing the acts specified in the flow chart and/or block diagram block or blocks.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers.

One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGAs, and the like.

Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or computer-readable storage media, which may be read and executed by one or more processors. Such instructions may be referred to as a computer program product. Computer readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, and any other volatile or nonvolatile, removable or non-removable media implemented in any technology. Computer storage media excludes signals per se and transitory forms of signal transmission. Communication media means any media that can be used for the communication of computer-readable information.

Aspects of the invention can be modified, if necessary, to employ the systems, functions, and concepts of the various references described above to provide yet further implementations of the invention. These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

To reduce the number of claims, certain aspects of the invention are presented below in certain claim forms, but the applicant contemplates other aspects of the invention in any number of claim forms. For example, while only one aspect of the invention is recited as a means-plus-function claim under 35 U.S.0 sec. 112(f) (AIA), other aspects may likewise be embodied as a means-plus-function claim, or in other forms, such as being embodied in a computer-readable medium. Any claims intended to be treated under 35 U.S.C. § 112(f) will begin with the words “means for,” but use of the term “for” in any other context is not intended to invoke treatment under 35 U.S.C. § 112(f). Accordingly, the applicant reserves the right to pursue additional claims after filing this application, in either this application or in a continuing application.

What is claimed is:

1. A dual-mode power amplifier simulation system comprising:
a trained machine learning model that is trained with first simulation results associated with a first power amplifier circuit and measured results associated with a physical implementation of the first power amplifier circuit, the trained machine learning model is configured to generate augmented simulation results;
a simulator executing on one or more computer processors that simulates a dual-mode power amplifier circuit and generates dual-mode simulation results; and
a post processor including the trained machine learning model that executes on one or more computing devices with computer-executable instructions that, when executed, causes the post processor to augment the dual-mode simulation results for the dual-mode power amplifier based on the trained machine learning model associated with the first power amplifier circuit.

2. The dual-mode power amplifier simulation system of claim 1 wherein the trained machine learning model is further trained with bill of material information about the first power amplifier circuit.

3. The dual-mode power amplifier simulation system of claim 2 wherein the trained machine learning model further receives bill of material information about the dual-mode power amplifier circuit.

4. The dual-mode power amplifier simulation system of claim 1 wherein the first power amplifier circuit and the dual mode power amplifier circuit are multi-chip modules.

5. The dual-mode power amplifier simulation system of claim 1 wherein the computer-executable instructions, when executed, further causes the one or more computer processors to retrain the trained machine learning model using second measured results obtained from the second electronic circuit.

6. The dual-mode power amplifier simulation system of claim 1 wherein the trained machine learning model uses a gradient tree boosting, ensemble model.

7. The dual-mode power amplifier simulation system of claim 1 wherein the trained machine learning model uses at least one of the group consisting of: linear regression, least absolute shrinkage and selection operator (LASSO), support vector regression (SVR), random forest algorithms, or bayesian ridge regression.

8. The dual-mode power amplifier simulation system of claim 1 wherein the trained machine learning model is trained to augment simulation results associated with at least one of the group consisting of: output power, error vector magnitude, current, and an output matching network (OMN).

9. The dual-mode power amplifier simulation system of claim 1 wherein the simulation results associated with the first power amplifier circuit, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.

10. The dual-mode power amplifier simulation system of claim 1 wherein the trained machine learning model reduces errors in the simulation results associated with the dual-mode power amplifier circuit, the errors including at least one of the group consisting of coding errors, thermal modeling errors, surface mount component (SMT) modeling errors, multi-chip module (MCM) modeling errors, mixed-signal integrated circuit errors, process variation errors, and harmonic balance errors.

11. The dual-mode power amplifier simulation system of claim 1 further comprising computer-executable code that generates first simulation results corresponding to the measured results.

12. A computer-implemented method comprising:
storing a trained machine learning model that is trained with first simulation results associated with a first power amplifier circuit and measured results obtained from a physical implementation of the first power amplifier circuit;
generating, with one or more computer processors, second simulation results associated with a dual-mode power amplifier circuit that is different than the first power amplifier circuit; and
augmenting the second simulation results with the trained machine learning model that executes on one or more computing devices with computer-executable instructions.

13. The computer-implemented method of claim 12 wherein the trained machine learning model is further trained with bill of material information about the first power amplifier electronic circuit.

14. The computer-implemented method of claim 12 wherein the trained machine learning model further receives bill of material information about the dual mode power circuit.

15. The computer-implemented method of claim 12 wherein the first power amplifier circuit includes a mode switch to adjust an output matching impedance, and the dual-mode power amplifier has an array of mode select switches to adjust an output matching impedance.

16. The computer-implemented method of claim 12 further comprising:
retraining the trained machine learning model using second measured results obtained from the dual-mode power amplifier circuit; and
augmenting third simulation results associated with another dual-mode power amplifier circuit with the retrained machine learning model.

17. The computer-implemented method of claim 12 wherein the trained machine learning model uses a gradient tree boosting, ensemble model.

18. The computer-implemented method of claim 12 wherein the trained machine learning model uses at least one of the group consisting of: linear regression, least absolute shrinkage and selection operator (LASSO), support vector regression (SVR), random forest algorithms, or bayesian ridge regression.

19. The computer-implemented method of claim 12 wherein the trained machine learning model is trained to augment simulation results associated with at least one of the group consisting of: output power, error vector magnitude, current, and an output matching network (OMN).

20. The computer-implemented method of claim 12 wherein the first simulation results, the measured results, and/or a bill of materials are used to train the trained machine learning model include at least one of the group consisting of: a surface mount component, a power amplifier variable, inductor data, capacitance data, input matching network (IMN) data, IMN inductor data, output matching network (OMN) data, OMN inductor data, OMN capacitor data, resistance data, resistance data, transistor base resistance (RBB), current, voltage, frequency, WiFi enable, multichip data, circuit architectural information, and silicon on insulator data.
